(19) United States
(12) Patent Application Publication
(10) Pub. No.: US 2026/0052916 A1
(43) Pub. Date: Feb. 19, 2026

(54) IN-SITU CYCLE ALE METHOD FOR DIELECTRIC DEPOSITION FULL-FILL ON NARROW TRENCH

(71) Applicant: Applied Materials, Inc., Santa Clara, CA (US)

(72) Inventors: Dongjoon KIM, Santa Clara, CA (US); Xiang JI, Sunnyvale, CA (US); Jung Chan LEE, San Jose, CA (US); Praket Prakash JHA, San Jose, CA (US); Jingmei LIANG, San Jose, CA (US)

(21) Appl. No.: 19/300,378

(22) Filed: Aug. 14, 2025

Related U.S. Application Data
(60) Provisional application No. 63/683,599, filed on Aug. 15, 2024.

(51) Int. Cl. H01L 21/02; C23C 16/04

(52) U.S. Cl. CPC H01L 21/0228; C23C 16/045; H01L 21/02274

(57) ABSTRACT

A device includes a substrate comprising a plurality of structures and a dielectric layer. A first structure of the plurality of structures is separated from a second structure of the plurality of structures by a first distance. Each structure of the plurality of structures has an aspect ratio of about 5:1 to about 15:1. The dielectric layer is disposed on an upper surface of the substrate, a first sidewall and a second sidewall of the plurality of structures, and an upper surface of the plurality of structures. The dielectric layer has a thickness of about 1 nm to about 5 nm on the sidewalls of the plurality of structures. A method of forming a device includes depositing the dielectric layer over the substrate. A portion of the dielectric layer is modified to form a modified dielectric layer. An atomic layer etch is performed to remove the modified dielectric layer.

### CROSS-REFERENCE TO RELATED APPLICATIONS

This application claims priority to U.S. Provisional Patent Application No. 63/683,599, filed Aug. 15, 2024, which is herein incorporated by reference in its entirety.

### BACKGROUND

### Field

Embodiments of the present invention generally relate to fabrication of microelectronic devices, and more specifically, relate to gap fill deposition and film densification during the fabrication of microelectronic devices.

### Description of the Related Art

Semiconductor device geometries have dramatically decreased in size since their introduction several decades ago. Moden semiconductor fabrication equipment routinely produces devices with feature sizes of 10 nm and sub-10 nm, and new equipment is being developed and implemented to make devices with even smaller geometries. The decreasing feature sizes result in structural features on the device having decreased spatial dimensions. The widths of gaps and trenches on the device narrow to a point where the aspect ratio of the gap depth to its width becomes high enough to make it challenging to fill the gap with dielectric material. As a result, the deposition of dielectric material is prone to clog at the top before the gap is completely filled, producing a void or seam in the middle of the gap.

Over the years, many techniques have been developed to avoid having dielectric material clog the top of a gap, or to “heal” the void or seam that has been formed. One approach has been to etch the dielectric material to remove the material clog at the top of the gap. Unfortunately, during the etching process, the dielectric material at the bottom of the gap etches faster than the top of the gap, reducing the thickness of the dielectric material at the bottom of the gap, and preventing uniform distribution. Conventionally, selective etching has been implemented to limit the bottom of the gap from etching at the same rate as the top of the gate. However, approaches to control etching selectivity of the dielectric material generally require adjusting one or more process conditions during the dielectric material deposition, leading to bubbles forming in the dielectric material.

Therefore, there is a need for an improved method of gap fill deposition.

### SUMMARY

In one embodiment, a device is disclosed. The device includes a substrate comprising a plurality of structures and a dielectric layer. A first structure of the plurality of structures is separated from a second structure of the plurality of structures by a first distance. Each structure of the plurality of structures has an aspect ratio of about 5:1 to about 15:1. The dielectric layer is disposed on an upper surface of the substrate, a first sidewall and a second sidewall of the plurality of structures, and an upper surface of the plurality of structures. The dielectric layer has a thickness of about 1 nm to about 5 nm on the first sidewall and the second sidewall of the plurality of structures.

In another embodiment, a method of forming a device is disclosed. The method includes depositing a dielectric layer over a substrate. A portion of the dielectric layer is modified to form a modified dielectric layer. An atomic layer etch is performed to remove the modified dielectric layer.

In yet another embodiment, a method of forming a device is disclosed. The method includes supplying a substrate to a processing chamber of one or more processing chambers of a cluster tool. A dielectric layer is deposited over the substrate within the processing chamber. A portion of the dielectric layer is modified to form a modified dielectric layer within the processing chamber. An atomic layer etch is performed to remove the modified dielectric layer within the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a cross-sectional view of a substrate, according to embodiments.

FIG. 2 is a schematic view of a cluster tool, according to embodiments.

FIG. 3A is a schematic view of a processing chamber, according to embodiments.

FIG. 3B is a schematic bottom view of a shower head, according to embodiments.

FIG. 4 is a schematic view of a plasma chamber, according to embodiments.

FIG. 5 is a flow diagram of a method of forming a device, according to embodiments.

FIGS. 6A-6D are cross-sectional view of a substrate during the method of FIG. 5, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to fabrication of microelectronic devices, and more specifically, relate to gap fill deposition and film densification during the fabrication of microelectronic devices.

Many of the details, components and other features described herein are merely illustrative of particular implementations. Accordingly, other implementations can have other details, components, and features without departing from the spirit or scope of the present disclosure. In addition, further implementations of the disclosure can be practiced without several of the details described below.

A “substrate” as used herein refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

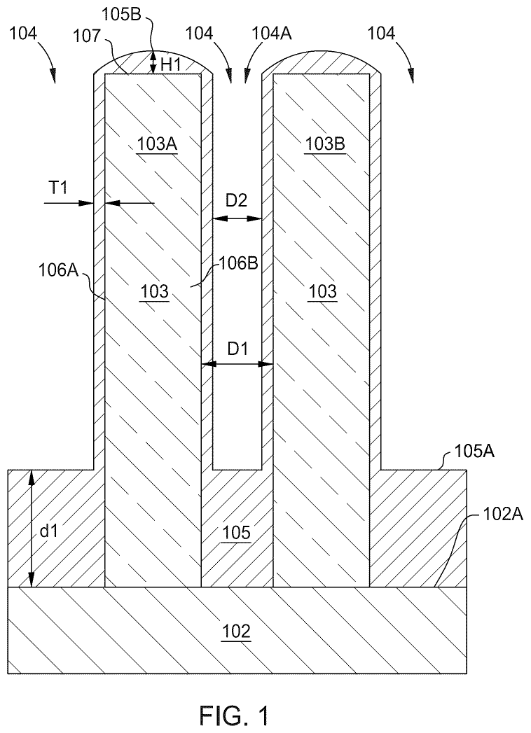

FIG. 1 is a cross-sectional view of a substrate 102. The substrate 102 includes a plurality of structures 103, such as a first structure 103A and a second structure 103B. Though the illustrated embodiment illustrates only a first structure 103A and a second structure 103B, the substrate 102 may include any number of structures 103. A distance D1 between adjacent structures 103 is less than about 30 nm, such as about 5 nm to about 25 nm, such as about 10 nm to about 20 nm, such as about 15 nm to about 25 nm. The structures have a high aspect ratio (height to width) of about 2:1 to about 20:1, such as about 5:1 to about 15:1, such as about 8:1 to about 12:1, such as about 10:1.

The plurality of structures 103 may include a multi-material layer formed of conductive material and utilized as part of an integrated circuit, such as gate electrodes, interconnect lines, and contact plugs. In some embodiments, the multi-material layer includes a number of stacked layers formed on the substrate 102. The multi-material layer may include first layers and second layers alternately formed over the substrate 102. In some examples, the multi-material layer may be formed of refractory metals, such as tungsten (W), molybdenum (Mo), tantalum (Ta), titanium (Ti), hafnium (Hf), vanadium (V), chromium (Cr), manganese (Mn), ruthenium (Ru), alloys thereof, silicide compounds thereof, nitride compounds thereof, or combinations thereof. In other examples, the first layers and the second layers may be other metals, such as copper (Cu), nickel (Ni), cobalt (Co), iron (Fe), aluminum (Al), palladium (Pd), gold (Au), silver (Au), platinum (Pt), alloys thereof, nitride compounds thereof, or combinations thereof. In one embodiment, the first layers are formed of silicon-germanium (SiGe) and the second layers are formed of silicon (Si). The multi-material layer may have a total thickness from about 0.2 μm to about 25 μm. The first layers may each have a thickness from about 10 nm to about 100 nm. The second layers may each have a thickness from about 10 nm to about 100 nm. The plurality of structures 103 define a plurality of trenches 104, such as trench 104A.

A dielectric layer 105 is disposed over the plurality of structures 103 and the substrate 102. The dielectric layer 105 includes a silicon nitride or a silicon oxide material. The dielectric layer 105 has a depth d1 from the upper surface 102A of the substrate 102 to an upper surface 105A of the dielectric material 105 within the trenches 104 of about 10 nm to about 30 nm, such as about 15 nm to about 25 nm, such as about 20 nm. The dielectric layer 105 has a height H1 from the upper surface 107 of the structure 103 to an upper surface 105B of the dielectric layer 105 disposed over the upper surface 107 of the structures 103 of about 10 nm to about 30 nm, such as about 15 nm to about 25 nm, such as about 20 nm. The dielectric layer 105 has a thickness T1 on a first sidewall 106A and a second sidewall 106B of the plurality of structures 103 of about 1 nm to about 5 nm, such as about 2 nm to about 4 nm, such as about 3 nm. As a result of the thickness T1, for example, a second distance D2 from the dielectric layer 105 on the sidewall 106 of the first structure 103A to the dielectric layer 105 on the sidewall 106 of the second structure 103B is less than about 25 nm, such as about 5 nm to about 25 nm, such as about 15 nm to about 20 nm, such as about 10 nm to about 20 nm. As a result of method 500, as described in further detail below, the second distance D2 is reduced, enabling more efficient gap fill procedures.

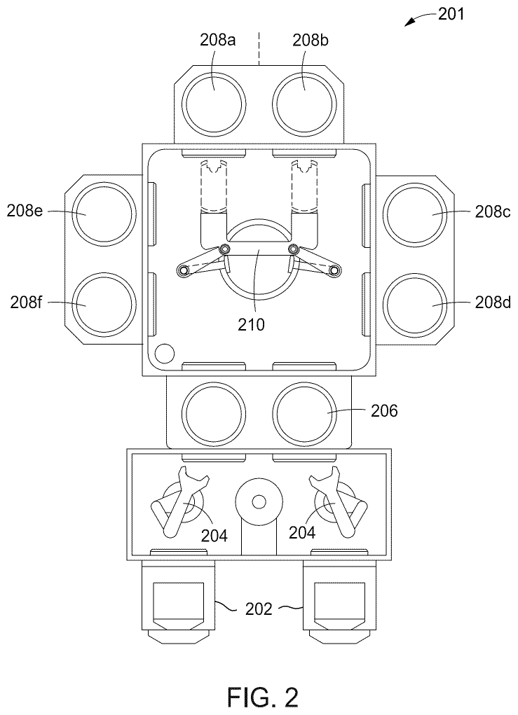

FIG. 2 is a cluster tool 201 that includes processing chambers 208a-f. Embodiments of the deposition systems and techniques may be incorporated into larger fabrication systems for producing integrated circuit chips. A pair of front opening unified pods (FOUPs) 202 supply substrates (e.g., 300 mm diameter wafers) that are received by robotic arms 204 and placed into a low pressure holding area 206. A second robotic arm 210 may be used to transport the substrate between the lower pressure holding area 206 and the processing chambers 208a-f.

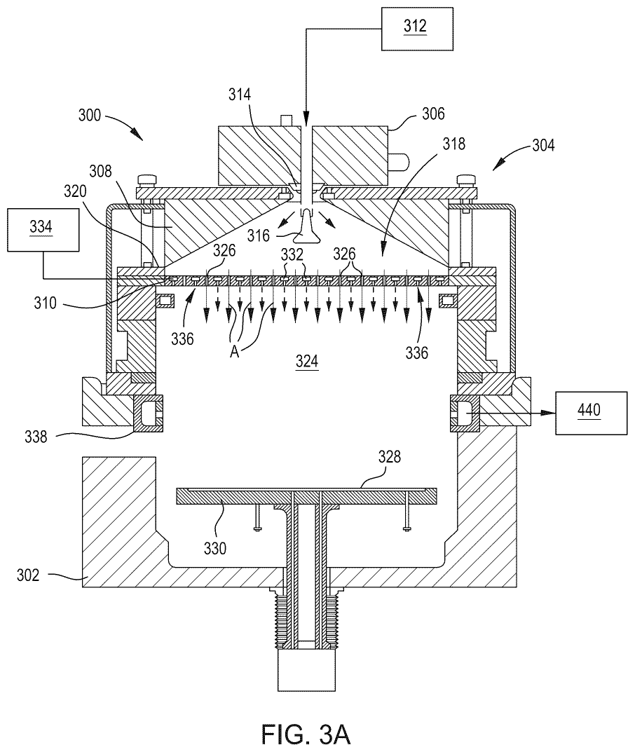

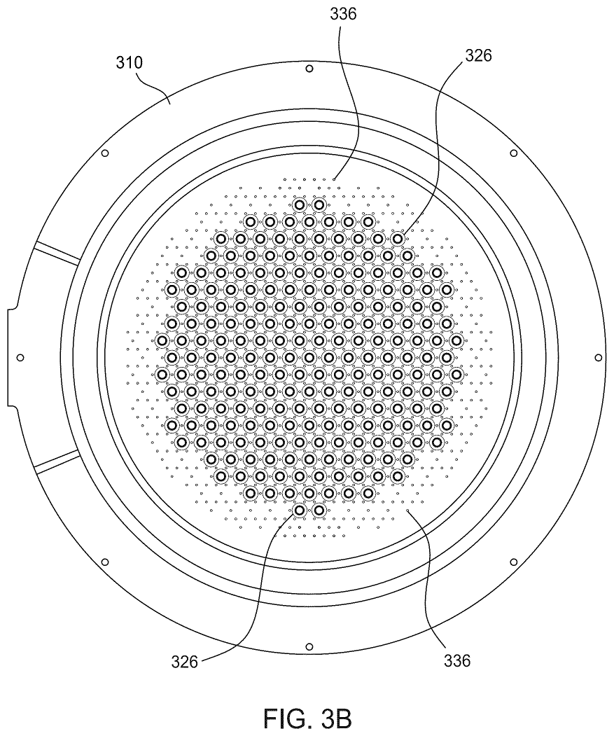

FIG. 3A is a schematic view of a processing chamber 300 having a chamber body 302 and lid assembly 304. The lid assembly 304 generally includes a remote plasma source (RPS) 306, a lid 308, and a dual channel showerhead (DCSH) 310. The RPS 306 may process a processing precursor gas provided from a processing precursor gas source 312. The plasma formed in the RPS 306 may be then delivered through a gas inlet assembly 314 and baffle 316, which are coupled to the lid 308, and into a chamber plasma region 318. A carrier gas (e.g., Ar, He, NF₃) may be delivered into the chamber plasma region 318. The lid 308 (that is a conductive top portion) and the dual channel showerhead (DCSH) 310 are disposed with an insulating ring 320 in between, which allows an AC potential to be applied to the lid 308 relative to the DCSH 310.

The DCSH 310 is disposed between the chamber plasma region 318 and a substrate processing region 324 and allows radicals activated in the plasma present within the chamber plasma region 318 to pass through a plurality of through-holes 326 into the substrate processing region 324. The flow of the radicals (radical flux) is indicated by the solid arrows “A” in FIG. 3A. A substrate 328 (e.g., substrate 102) is disposed on a substrate support 330 disposed within the substrate processing region 324. The DCSH 310 also has one or more hollow volumes 332 which can be filled with a dielectric precursor provided from a precursor source 334. The dielectric precursor passes from the one or more hollow volumes 332 through small holes 336 and into the substrate processing region 324, bypassing the chamber plasma region 318. The flow of the dielectric precursor is indicated by the dotted arrows in FIG. 3A. An exhaust ring 338 is used to uniformly evacuate the substrate processing region 324 by use of an exhaust pump 340. The DCSH 310 may be thicker than the length of the smallest diameter of the through-holes 326. The length of the smallest diameter of the through-holes 326 may be restricted by forming larger diameter portions of through-holes 326 partially through the DCSH 310, to maintain a flow of radical flux from the chamber plasma region 318 into the substrate processing region 324. In some embodiments, the length of the smallest diameter of the through-holes 326 may be the same order of magnitude as the smallest diameter of the through-holes 326 or less.

In some embodiments, a pair of processing chambers (e.g., 208c-d) in FIG. 2 (referred to as a twin chamber) may be used to deposit a dielectric precursor on the substrate. Each of the processing chambers (e.g., 208c-d) can have a cross-sectional structure of the processing chamber 300 depicted in FIG. 3A. The flow rates per channel of the DCSH described above correspond to flow rates into each of the chambers (e.g., 208c-d) via the corresponding DCSH 310.

FIG. 3B is a schematic bottom view of the DCSH 310. The DCSH 310 may deliver via through-holes 326 the radical flux and the carrier gas present within the chamber plasma region 318.

In some embodiments, the number of through-holes 326 may be about 60 holes to about 2000 holes. Through-holes 326 may have round shapes or a variety of shapes. In some embodiments, the smallest diameter of through-holes 326 may be about 0.5 mm to about 20 mm, such as about 1 mm to about 6 mm. The cross-sectional shape of through-holes 326 may be made conical, cylindrical or a combination of the two shapes. In some embodiments, a number of small holes 336 may be used to introduce a dielectric precursor into the substrate processing region 324 and may be about 100 holes to about 5000 holes or about 500 holes to about 2000 holes. The diameter of the small holes 336 may be about 0.1 mm to about 2 mm.

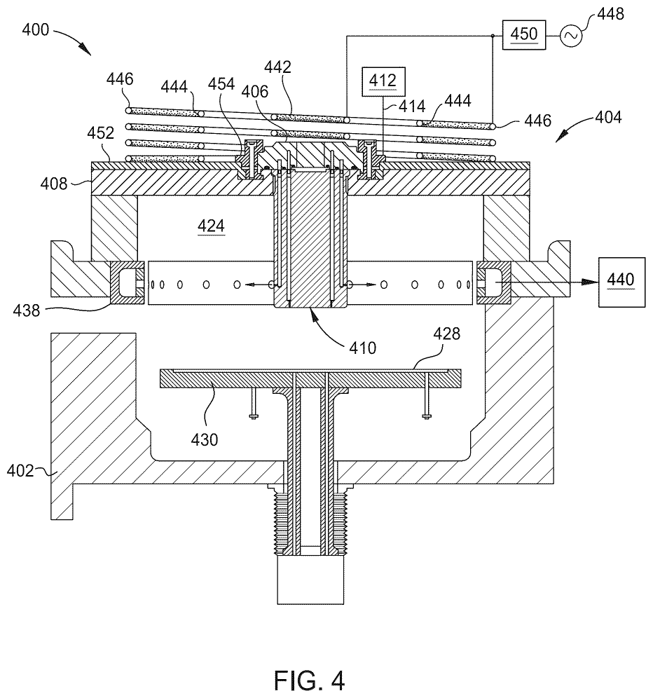

FIG. 4 is a schematic view of a plasma chamber 400 having a chamber body 402 and lid assembly 404. The lid assembly 404 includes a gas delivery assembly 406 and a lid 408. The lid 408 has an opening 410 to allow entrance of one or more processing precursor gases. The gas delivery assembly 406 is disposed over the lid 408 through the opening 410. The gas delivery assembly 406 may be connected to a gas source 412 through a gas inlet 414 to supply one or more processing precursor gases into a substrate processing region 424. A substrate 428 is disposed on a substrate support 430 disposed within the substrate processing region 424 and coupled to a bias power source (not shown). The one or more processing precursor gases may exit the substrate processing region 424 by use of an exhaust ring 438 and an exhaust pump 440.

In the lid assembly 404, inner coils 442, middle coils 444, and outer coils 446 are disposed over the lid 408. The inner coils 442 and the outer coils 446 are coupled to an RF power source 448 through a matching circuit 450. Power applied to the outer coils 446 from the RF power source 448 is inductively coupled through the lid 408 to generate plasma from the processing precursor gases provided from the gas source 412 within the substrate processing region 424. The RF power source 448 can provide current at different frequencies to control the plasma density (i.e., number of ions per cc) in the plasma and thus the density of ion flux (ions/cm²·sec). The bias power source controls a voltage between the substrate 428 and the plasma, and thus controls the energy and directionality of the ions. Thus, both ion flux and ion energy can be independently controlled. A heater assembly 452 may be disposed over the lid 408. The heater assembly 452 may be secured to the lid 408 by clamping members 454, 456.

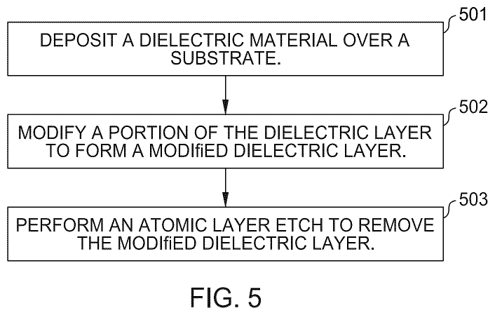

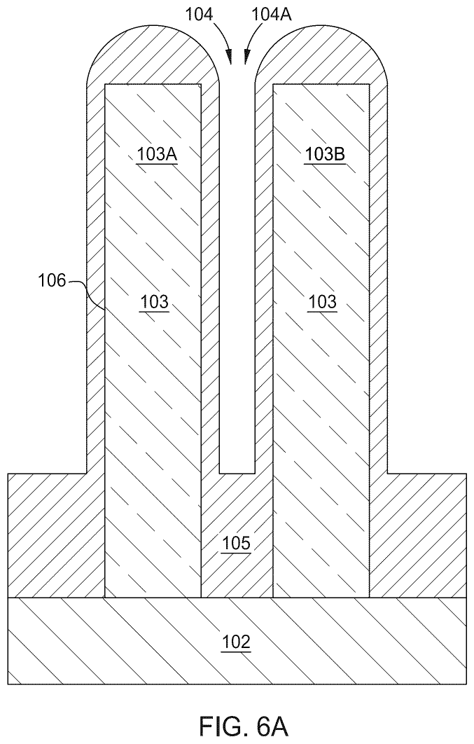

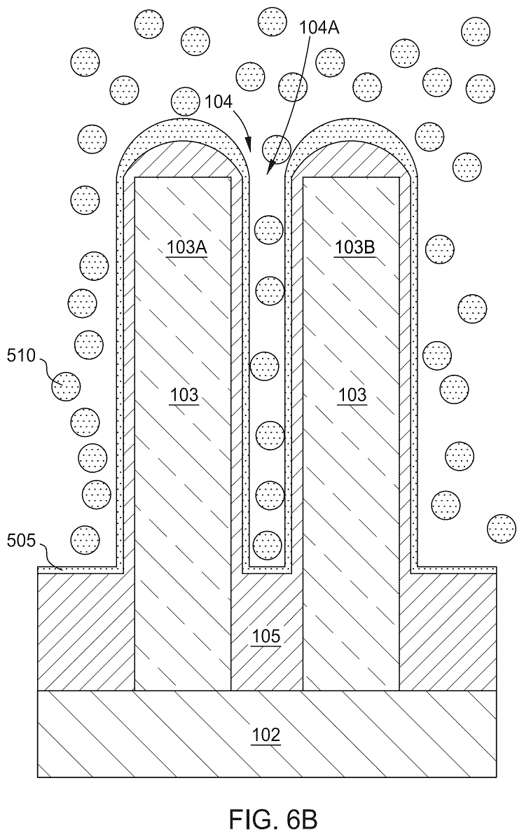

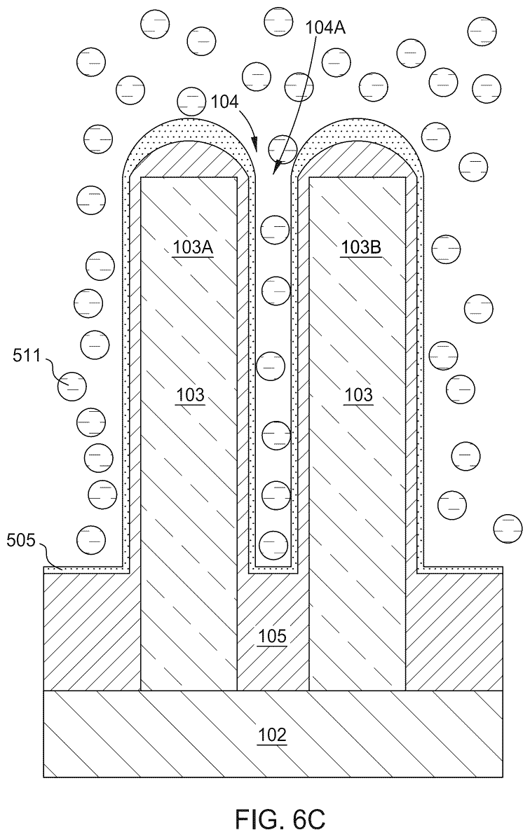

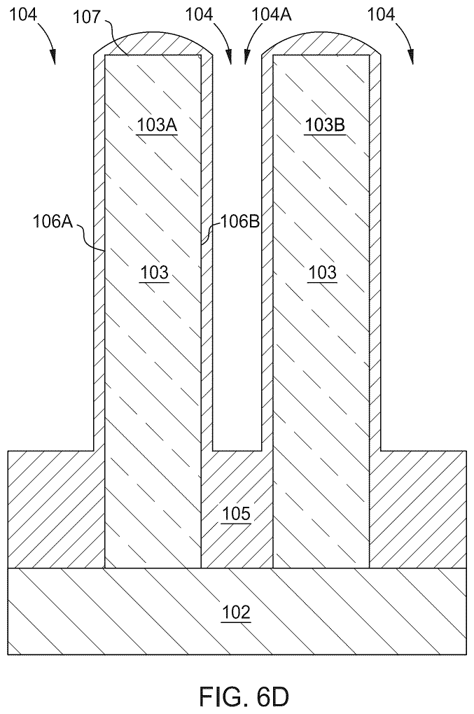

FIG. 5 is a flow diagram of a method of forming a device, such as substrate 102. FIGS. 6A-6D are cross-sectional view of a substrate 102 during the method 500. At operation 501, as shown in FIG. 6A, a dielectric material 105 is deposited over the substrate 102. The substrate 102 includes a plurality of structures 103, such as a first structure 103A and a second structure 103B. In some embodiments, the dielectric material 105 includes a silicon nitride or a silicon oxide.

At operation 502, as shown in FIG. 6B, a portion of the dielectric layer 105 is modified to form a modified dielectric layer 505. A hydrogen plasma 510 is introduced into the process chamber 300 or plasma chamber 400. The hydrogen plasma 510 modifies the surface of the dielectric layer 105 to form the modified dielectric layer 505. The modification of the dielectric layer 105 is performed at a pressure of about 0.5 Torr to about 5 Torr, such as about 1 Torr to about 3 Torr, such as about 1.5 Torr. The substrate 102 is maintained at a temperature of about 300° C. to about 600° C., such as about 350° C. to about 550° C., such as about 400° C. to about 500° C. The dielectric layer 105 is exposed to the hydrogen plasma 510 for about 5 second to about 25 seconds, such as about 10 seconds to 20 seconds, such as about 15 seconds. The hydrogen plasma 510 is formed from a hydrogen gas using a HF RF of about 27 MHz. The flow rate of the hydrogen gas is about 500 sccm to about 2500 sccm, such as about 1000 sccm to about 2000 sccm, such as about 1500 sccm. The modified dielectric layer 505 may be about 1 Å to about 10 Å.

At operation 503, as shown in FIG. 6C and FIG. 6D, atomic layer etching (ALE) is performed to remove the modified dielectric layer 505. In some embodiments, the ALE process is performed in the same processing chamber as the densified seam free deposition of the dielectric material 105. The ALE process is performed using a plasma of a fluorine containing gas 511, such as NF₃ (or a combination of fluorine containing gas and argon). The RF power used during the ALE etching to form a fluorine plasma 511 from the fluorine containing gas and argon is a HF RF of about 27 MHz and at about 50 W to about 150 W, such as about 75 W to about 125 W, such as about 100 W. The flow rate of the argon gas during the ALE process is about 3000 sccm to about 6000 sccm, such as about 3500 to about 5500 sccm, such as about 4000 sccm to about 5000 sccm. The flow rate of the fluorine gas is about 30 sccm to about 60 sccm, such as about 35 to about 55 sccm, such as about 40 sccm to about 50 sccm. The substrate 102 is maintained at a temperature of about 350° C. to about 500° C., such as about 400° C. to about 450° C. during the ALE process. The processing chamber is maintained at a pressure of about 2 Torr to about 6 Torr, such as about 3 Torr to about 5 Torr, during the ALE process.

The fluorine plasma 511 of ALE process etches and removes the modified dielectric layer 505, reducing the thickness T1 of the dielectric layer 105 on the sidewall 106 of the plurality of structures 103. The ALE process does not affect the unmodified dielectric layer 105. While the depth d1 and the height H1 of the dielectric layer 105 are also reduced during the ALE process, the relative amount of the dielectric layer 105 that is etched from the depth d1 and the height H1 is less significant compared to the amount of dielectric material 105 etched from the sidewalls 106 of the plurality of structures 103. Without being bound to any particular theory of operation, it is believed that the higher hydrogen content of the modified dielectric layer 505 makes the modified dielectric layer 505 more susceptible to etching by the fluorine plasma 511.

The ALE process is cyclically performed on the modified dielectric layer 505 until the modified dielectric layer 505 is completely removed. Each etching cycle is performed in less than about 1 second, such as less than about 0.5 seconds, such as about 0.25 seconds. Without being bound by theory, it is believed that a shorter cycle time (e.g., a shorter amount of time the dielectric layer 105 is exposed to the fluorine plasma 511) maintains the etching selectivity between the modified dielectric layer 505 and the dielectric layer 105, e.g., if the cycle time is longer, the likelihood of etching the dielectric layer 105 is increased.

Overall, various embodiments of the present disclosure allow for the in-situ selective etching of the sidewalls of the structures within the gap without etching, or with limited etching, of the bottom of the gap, increasing the uniformity of the dielectric material in the gap. The process may be performed at high temperature and high pressures, and results in cost reduction benefits due to process integration.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate comprising a plurality of structures, wherein a first structure of the plurality of structures is separated from a second structure of the plurality of structures by a first distance, wherein each structure of the plurality of structures has an aspect ratio of about 5:1 to about 15:1; and
a dielectric layer disposed on an upper surface of the substrate, a first sidewall and a second sidewall of the plurality of structures, and an upper surface of the plurality of structures, wherein the dielectric layer has a thickness of about 1 nm to about 5 nm on the first sidewall and the second sidewall of the plurality of structures.

2. The device of claim 1, wherein the dielectric layer comprises silicon oxide or silicon nitride.

3. The device of claim 1, wherein the plurality of structures define a plurality of trenches, and wherein a depth of the dielectric layer in the plurality of trenches is about 10 nm to about 30 nm.

4. The device of claim 1, wherein a height of the dielectric layer disposed over the upper surface of the plurality of structures is about 10 nm to about 30 nm.

5. The device of claim 1, wherein plurality of structures include a multi-material layer formed of conductive material.

6. The device of claim 5, wherein the conductive material comprises tungsten (W), molybdenum (Mo), tantalum (Ta), titanium (Ti), hafnium (Hf), vanadium (V), chromium (Cr), manganese (Mn), ruthenium (Ru), as copper (Cu), nickel (Ni), cobalt (Co), iron (Fe), aluminum (AI), palladium (Pd), gold (Au), silver (Au), platinum (Pt), silicon germanium (SiGe), silicon (Si), alloys thereof, silicide compounds thereof, nitride compounds thereof, or combinations thereof.

7. The device of claim 1, wherein a second sidewall of the first structure and a first sidewall of the second structure are separated by a distance of about 5 nm to about 25 nm.

8. A method of forming a device, comprising:
depositing a dielectric layer over a substrate;
modifying a portion of the dielectric layer to form a modified dielectric layer; and
performing an atomic layer etch to remove the modified dielectric layer.

9. The method of claim 8, wherein performing an atomic layer etch comprises performing a cyclic atomic layer etch, wherein each cycle of the atomic layer etch is less than about 0.5 seconds.

10. The method of claim 8, wherein performing the atomic layer etch comprises using a plasma from fluorine-containing gas or a mixture of the fluorine-containing gas and an argon gas.

11. The method of claim 10, wherein the fluorine gas is NF₃.

12. The method of claim 8, wherein the modifying of the portion of dielectric layer comprises forming a modified dielectric layer having a thickness of about 1 Å to about 10 Å.

13. The method of claim 8, wherein performing the atomic layer etch comprises maintaining the substrate at a temperature of about 350° C. to about 500° C.

14. The method of claim 8, wherein performing the atomic layer etch comprises maintaining the substrate at a pressure of about 2 Torr to about 6 Torr.

15. The method of claim 8, wherein the modifying of the portion of dielectric layer comprises modifying the dielectric layer with a hydrogen plasma.

16. The method of claim 8, wherein depositing the dielectric layer over the substrate comprises depositing the dielectric layer over a plurality of structures of the substrate, wherein the plurality of structures have an aspect ratio of about 5:1 to about 15:1.

17. The method of claim 16, wherein performing the atomic layer etch to remove the modified dielectric layer comprises forming a dielectric layer having a thickness of about 1 nm to about 5 nm on a first sidewall and a second sidewall of each of the plurality of structures.

18. A method of forming a device, comprising:
supplying a substrate to a processing chamber of one or more processing chambers of a cluster tool;
depositing a dielectric layer over the substrate within the processing chamber;
modifying a portion of the dielectric layer to form a modified dielectric layer within the processing chamber; and
performing an atomic layer etch to remove the modified dielectric layer within the processing chamber.

19. The method of claim 18, wherein the processing chamber comprises:
a chamber body; and
a lid assembly, the lid assembly comprising:
a remote plasma source;
a lid; and
a dual channel showerhead.

20. The method of claim 19, wherein:
the modifying of the portion of dielectric layer comprises:
forming a modified dielectric layer comprises modifying the dielectric layer with a hydrogen plasma supplied to the chamber via the lid assembly; and
form a modified dielectric layer having a thickness of about 1 Å to about 10 Å; and
performing the atomic layer etch comprises:
performing a cyclic atomic layer etch, wherein each cycle of the atomic layer etch is less than about 0.5 seconds;
using a plasma from a fluorine-containing gas supplied to the chamber body via the lid assembly;
maintaining the substrate a temperature of about 350° C. to about 500° C.; and
maintaining a substrate processing region within the chamber body at a pressure of about 2 Torr to about 6 Torr.
